(19) United States
(12) Patent Application Publication
(10) Pub. No.: US 2024/0316488 A1
(43) Pub. Date: Sep. 26, 2024

(54) CLEANING APPARATUS, LITHOGRAPHY APPARATUS, AND ARTICLE MANUFACTURING METHOD

(71) Applicant: CANON KABUSHIKI KAISHA, Tokyo (JP)

(72) Inventor: SHINTARO AICHI, Tochigi (JP)

(21) Appl. No.: 18/603,679

(22) Filed: Mar. 13, 2024

(30) Foreign Application Priority Data
Mar. 22, 2023 (JP) 2023-045787

(51) Int. Cl. B01D 53/04; B01D 53/30; G01N 5/02; G03F 7/00; H01L 21/027

(52) U.S. Cl. CPC B01D 53/0454; B01D 53/0407; B01D 53/30; G01N 5/025; G03F 7/0002; H01L 21/027; B01D 2253/102

(57) ABSTRACT

The present invention provides a cleaning apparatus for performing gas cleaning in a chamber, comprising: a gas flow path configured to receive a gas in the chamber and send the gas to the chamber; a filter arranged in the gas flow path and configured to adsorb an organic substance in a gas flowing through the gas flow path; a weight measurement device configured to measure a weight of the filter; a humidity detector configured to detect a humidity of a gas in the gas flow path; and a controller configured to control the gas cleaning, wherein the controller is configured to estimate an adsorption state of an organic substance in the filter based on a measurement result of the weight measurement device and a detection result of the humidity detector.

### BACKGROUND OF THE INVENTION

### Field of the Invention

The present invention relates to a cleaning apparatus, a lithography apparatus, and an article manufacturing method.

### Description of the Related Art

A cleaning apparatus including a filter for adsorbing an organic substance in air to clean a gas (for example, air) in a chamber for performing processing for forming a pattern on a substrate is arranged in a lithography apparatus. In this cleaning apparatus, an adsorption state of the organic substance in the filter is required to determine the replacement timing of the filter. Japanese Patent Laid-Open No. 2007-311722 describes a method of detecting the lifetime of a chemical filter based on the transmittance of an optical member when the optical member is arranged in an exposure apparatus to be exposed in a downstream gas of the chemical filter arranged in an air-conditioning system and the optical member is irradiated with light having the same wavelength as in an exposure step.

In the method described in Japanese Patent Laid-Open No. 2007-311722, it is necessary to arrange the optical member, and it is also necessary to guide light having the same wavelength as in the exposure step to the optical member and measure the transmittance of the optical member, thereby complicating the apparatus arrangement.

### SUMMARY OF THE INVENTION

The present invention provides, for example, a technique advantageous in obtaining the adsorption state of an organic substance in a filter of a cleaning apparatus easily with high precision.

According to one aspect of the present invention, there is provided a cleaning apparatus for performing gas cleaning in a chamber, comprising: a gas flow path configured to receive a gas in the chamber and send the gas to the chamber; a filter arranged in the gas flow path and configured to adsorb an organic substance in a gas flowing through the gas flow path; a weight measurement device configured to measure a weight of the filter; a humidity detector configured to detect a humidity of a gas in the gas flow path; and a controller configured to control the gas cleaning, wherein the controller is configured to estimate an adsorption state of an organic substance in the filter based on a measurement result of the weight measurement device and a detection result of the humidity detector.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of a cleaning apparatus according to the first embodiment;

FIGS. 2A and 2B are views showing the breakdown of the weight of a chemical filter;

FIG. 3 is a view showing an example of humidity-water content information;

FIG. 4 is a view showing the relationship between the use period (the number of days) of the chemical filter and the adsorption amount of an organic substance;

FIG. 5 is a schematic view showing an example of the arrangement of a cleaning apparatus according to the second embodiment; and

FIG. 6 is a schematic view showing an example of the arrangement of a lithography apparatus (imprint apparatus).

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

### First Embodiment

A cleaning apparatus 100 according to the first embodiment of the present invention will be described below. The cleaning apparatus 100 according to this embodiment is an apparatus for performing gas cleaning in a chamber CMB in which a forming portion for forming a pattern on a substrate is accommodated. The cleaning apparatus 100 can be understood as an environment control apparatus for controlling the environment in the chamber.

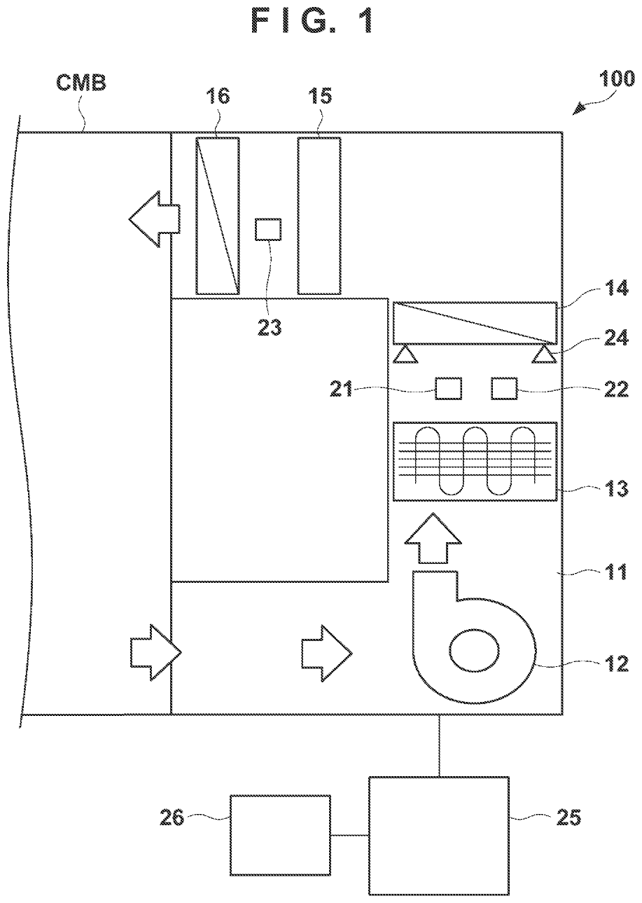

FIG. 1 is a schematic view showing an example of the arrangement of the cleaning apparatus 100 according to the first embodiment. The cleaning apparatus 100 according to this embodiment can include a gas flow path 11, a blower 12, a cooling device 13, a chemical filter 14, a heating device 15, and a particle capturing filter 16. The blower 12, the cooling device 13, the chemical filter 14, the heating device 15, and the particle capturing filter 16 are arranged in the gas flow path 11. In addition, the cleaning apparatus 100 can include a humidity detector 21, temperature detectors 22 and 23, a weight measurement device 24, a controller 25, and a notification device 26. Note that arrows in FIG. 1 indicate the flows of a gas.

The gas flow path 11 (air flow path) is arranged to receive the gas (for example, air) in the chamber CMB and send out the gas to the chamber CMB. The gas flow path 11 may be understood to arrange part of a circulation system for circulating the gas in the chamber CMB. In the arrangement example in FIG. 1, the gas flow path 11 is arranged to receive only the gas in the chamber CMB. However, the gas flow path 11 may be arranged to receive a gas outside the chamber CMB in addition to the gas in the chamber CMB.

The blower 12 sends the gas in the gas flow path 11. By the operation of the blower 12, the gas can be circulated so that the gas in the chamber CMB is received by the gas flow path 11 and sends the gas received by the gas flow path 11 to the chamber CMB. Note that in the arrangement example in FIG. 1, the blower 12 is arranged on the upstream side of the cooling device 13 in the gas flow path 11, but the arrangement position of the blower 12 is not limited to this. The position of the blower 12 is arbitrary if the gas flow can be formed in the gas flow path.

The cooling device 13 cools the gas received by the gas flow path 11. The cooling device 13, for example, arranged as a heat-exchanger for cooling the gas. The gas passing through the cooling device 13 is supplied to the chemical filter 14. The chemical filter 14 is a filter for adsorbing the organic substance in the gas flowing in the gas flow path 11. When the gas passes through the chemical filter 14, the organic substance in the gas is reduced (removed). The gas passing through the chemical filter 14 is adjusted to a predetermined temperature by the heating device 15, and then the gas is sent to the chamber CMB via the particle capturing filter 16. The particle capturing filter 16 is a filter for capturing particles in the gas flowing through the gas flow path 11. An HEPA filter or a ULPA filter is used as the particle capturing filter 16.

The humidity detector 21 (humidity sensor) detects the humidity of the gas in the gas flow path 11. In this embodiment, the humidity detector 21 is arranged to detect the humidity of the gas on the upstream side of the chemical filter 14 in the gas flow path 11. More specifically, as shown in FIG. 1, the humidity detector 21 is arranged between the cooling device 13 and the chemical filter 14 to detect the humidity of the gas cooled by the cooling device 13.

The temperature detector 22 (temperature sensor) detects the temperature of the gas in the gas flow path 11. In this embodiment, the temperature detector 22 is arranged to detect the temperature of the gas on the upstream side of the chemical filter 14 in the gas flow path 11. More specifically, as shown in FIG. 1, the temperature detector 22 is arranged between the cooling device 13 and the chemical filter 14 to detect the temperature of the gas cooled by the cooling device 13.

The temperature detector 23 (temperature sensor) detects the temperature of the gas heated by the heating device 15. In this embodiment, the temperature detector 23 is arranged between the heating device 15 and the particle capturing filter 16. When the temperature detector 23 is arranged in this manner, the controller 25 can control the heating device 15 based on the detection result of temperature detector 23 so that the temperature of the gas heated by the heating device 15 is set at a predetermined temperature. That is, the gas whose temperature is adjusted to the predetermined temperature by the heating device 15 is supplied from the gas flow path 11 to the chamber CMB, thereby precisely adjusting the temperature in the chamber CMB.

The weight measurement device 24 measures the weight of the chemical filter 14. In this embodiment, as will be described later, the weight measurement device 24 can be used to estimate the adsorption state of the organic substance in the chemical filter 14. In this case, the chemical filter 14 which adsorbs the organic substance generally includes activated carbon as a filter material. The total capacity (to be referred to as an adsorption capacity hereinafter) capable of adsorbing (capturing) the organic substance by the chemical filter 14 can fall within the range of 5% to 10% of the weight of the chemical filter 14. For example, if the chemical filter 14 of 10 kg is used, the adsorption capacity is 500 to 1,000 g. Accordingly, the weight measurement device 24 preferably has a measurement resolution on the unit of 1 g (preferably unit of 0.1 g). Note that in this embodiment, the adsorption capacity can be defined as a weight.

The controller 25 is arranged by a computer (information processing unit) including a processor such as a central processing unit (CPU) and a storage unit such as a memory and controls the respective components of the cleaning apparatus 100. The controller 25 according to this embodiment controls the blower 12, the cooling device 13, and heating device 15 to control cleaning and temperature adjustment of the gas in the chamber CMB. In addition, the controller 25 according to this embodiment estimates the adsorption state of the organic substance in the chemical filter 14 based on the measurement result of the weight measurement device 24 and the detection result of the humidity detector 21. Further, the controller 25 according to this embodiment determines the replacement timing (replacement period) of the chemical filter 14 based on the adsorption state of the organic substance estimated for the chemical filter 14.

The notification device 26 notifies the user of various pieces of information by displaying the various pieces of information on a display device (display) serving as a user interface or by transmitting the various pieces of information to an information terminal owned by the user. In this embodiment, the notification device 26 can be used to notify the adsorption state of the organic substance in the chemical filter 14 or the replacement timing of the chemical filter 14.

### [Method of Estimating Adsorption State of Organic Substance]

A method of estimating the adsorption state of the organic substance in the chemical filter 14 by the controller 25 will be described below. The controller 25 can estimate, as the adsorption state of the organic substance in the chemical filter 14, the adsorption amount or the adsorbable amount in the chemical filter 14. The adsorption amount of the organic substance in the chemical filter 14 is an amount of organic substance already adsorbed in the chemical filter 14 and can also be simply referred to as the “adsorption amount” hereinafter. In addition, the adsorbable amount of the organic substance in the chemical filter 14 is an amount of organic substance adsorbable yet in the chemical filter 14, that is, the amount of the organic substance adsorbable by the chemical filter 14 in the future and is simply referred to as the “adsorbable amount” hereinafter. In this embodiment, the adsorption amount and the adsorbable amount can be defined by weights.

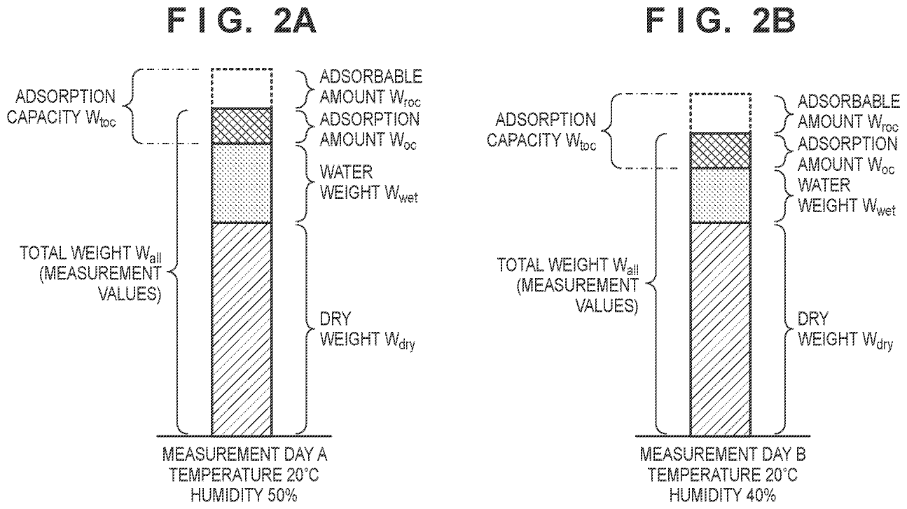

FIGS. 2A and 2B are views showing the breakdown of the weight of the chemical filter 14. FIGS. 2A and 2B exemplify different measurement days of the weight of the chemical filter 14 by the weight measurement device 24. FIG. 2A shows the breakdown of the weight of the chemical filter 14 in a measurement day A. The temperature in the chamber CMB in the measurement day A is 20 C°, and the humidity is 50%. FIG. 2B shows the breakdown of the weight of the chemical filter 14 in a measurement day B. The temperature in the chamber CMB in the measurement day B is 20 C°, and the humidity is 40%.

As indicated by equation (1) below, the controller 25 can estimate, as an adsorption amount W_{oc}, a value obtained by excluding a dry weight W_{dry} and a water weight W_{wet} of the chemical filter 14 from a total weight Wₐₗₗ of the chemical filter 14 as the measurement values of the weight measurement device 24. In addition, as indicated by equation (2) below, the controller 25 can estimate, as an adsorbable amount W_{roc}, a value obtained by subtracting the adsorption amount W_{oc} from the adsorption capacity W_{toc}.

$${W}_{oc} = {W}_{all} - {W}_{dry} - {W}_{wet} \qquad ( 1 )$$

$${W}_{roc} = {W}_{toc} - {W}_{oc} \qquad ( 2 )$$

In this case, the dry weight W_{dry} of the chemical filter 14 can be defined as the weight of the chemical filter 14 in a state (that is, a dry state) in which the organic substance is not adsorbed yet and no water is contained. The dry weight W_{dry} of the chemical filter 14 can be obtained from the specifications of the chemical filter 14. However, if the dry weight W_{dry} is not described in the specifications, it can be obtained by an experiment. For example, the dry weight W_{dry} of the chemical filter 14 can be obtained based on the result of measuring the weight of the chemical filter 14 in a state in which the chemical filter 14 is located in the atmosphere of the gas having a known reference humidity. The chemical filter 14 located in the atmosphere of the gas having the known reference humidity can contain the water amount corresponding to the reference humidity. For this reason, the water amount (weight) contained in the chemical filter 14 can be calculated based on the reference humidity. Therefore, the calculated water amount is subtracted from the measurement value of the weight of the chemical filter 14 to obtain the dry weight W_{dry}.

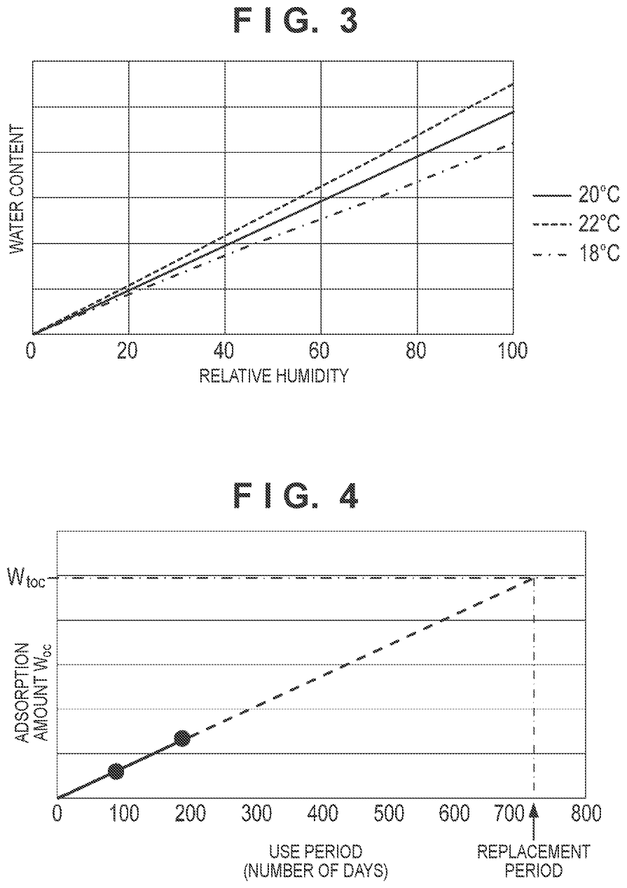

The water weight W_{wet} contained in the chemical filter 14 can be determined (calculated) based on information (to be referred to as humidity-water content information hereinafter) representing the relationship between the humidity of the gas in the gas flow path 11 and the water content of the chemical filter 14. FIG. 3 shows an example of humidity-water content information. The abscissa in FIG. 3 represents the relative humidity in the gas flow path 11, and the ordinate represents the water content of the chemical filter 14. The relative humidity is defined as a ratio of the water amount (steam) actually contained to the maximum water amount (saturation steam amount) which can be contained in the gas (for example, in the air) at a given temperature. The water content of the chemical filter 14 can be defined as the water amount (weight) contained in the chemical filter 14 located in the atmosphere of the relative humidity.

In this embodiment, as shown in FIG. 3, the controller 25 has the humidity-water content information for each temperature of the gas in the gas flow path 11. The controller 25 then determines the water content of the chemical filter 14 from the detection result (the humidity of the gas in the gas flow path 11) of the humidity detector 21 on the basis of the humidity-water content information selected in accordance with the detection result (the temperature of the gas in the gas flow path 11) of the temperature detector 22. Note that FIG. 3 shows the humidity-water content information when the temperatures of the gas in the gas flow path 11 are 18° C., 20° C., and 22° C. This is merely an example, and the temperature is not limited to these temperatures.

In this case, the humidity-water content information can be generated in advance by an experiment or the like. The results obtained by measuring the weight of the chemical filter 14 in a state in which the chemical filter 14 is located in the atmosphere of the gas having a predetermined temperature and a predetermined humidity are obtained for states at different humidities. Accordingly, the humidity-water content information can be generated for the corresponding temperature. This experiment is conducted by changing the temperature of the atmosphere to generate the humidity-water content information for each temperature.

### [Method of Determining Replacement Timing of Chemical Filter}

A method of determining the replacement timing of the chemical filter 14 by the controller 25 will be described below. The controller 25 can determine the replacement timing of the chemical filter 14 based on the adsorption state (adsorption amount W_{oc} or adsorbable amount W_{roc}) estimated for the chemical filter 14. For example, the controller 25 can determine the replacement timing of the chemical filter 14 based on information indicating the adsorption state of the chemical filter 14 for the use period (for example, the number of days) of the chemical filter 14. In addition, the controller 25 notifies the user (operator) of the determined replacement timing of the chemical filter 14 via the notification device 26.

FIG. 4 shows the relationship between the use period (the number of days) and the adsorption amount W_{oc} of the organic substance in the chemical filter 14. The controller 25 can determine, as the replacement timing of the chemical filter 14, the period (the number of days) during which the adsorption amount W_{oc} reaches the adsorption capacity W_{toc} based on the adsorption amount W_{oc} estimated at least twice. More specifically, the controller 25 determines, as the replacement timing of the chemical filter 14, the period (the number of days) during which an approximate line is obtained for the adsorption amount W_{oc} estimated at least twice, and the approximate line intersects the adsorption capacity W_{toc}.

As described above, in the cleaning apparatus 100 of this embodiment, the adsorption state of the organic substance in the chemical filter 14 is estimated based on the measurement result of the weight measurement device 24 and the detection result of the humidity detector 21. Accordingly, the complex apparatus arrangement can be simplified, and the adsorption state of the organic substance in the chemical filter 14 can be easily obtained with high precision.

In the cleaning apparatus 100 of this embodiment, the plurality of chemical filters 14 may be stacked. In this case, the weight measurement device 24 may be arranged to measure the total weight of the plurality of chemical filters 14 or may be arranged to measure the weight of each of the plurality of chemical filters 14. In addition, the cleaning apparatus 100 may arrange a filter (to be referred to as an inorganic substance filter hereinafter) for adsorbing the inorganic substance in the gas flowing through the gas flow path 11. Note that in this case, the weight measurement device 24 should not be arranged to measure the total weight of the chemical filter 14 and the inorganic substance filter because the inorganic substance filter has a characteristic for reducing the weight when the inorganic substance is adsorbed (captured). That is, if the weight measurement device 24 measures the total weight of the chemical filter 14 and the inorganic substance filter, it is difficult to precisely estimate the adsorption state of the organic substance in the chemical filter 14 based on the measurement result of the weight measurement device 24. Accordingly, if the inorganic substance filter is arranged, the weight of the chemical filter 14 is preferably measured independently of the inorganic substance filter. Note that the weight of the chemical filter 14 may be measured by a measurement device arranged outside the cleaning apparatus 100. In this case, the controller 25 can estimate the adsorption state of the organic substance in the chemical filter 14 based on the measurement result of the externally arranged measurement apparatus.

### Second Embodiment

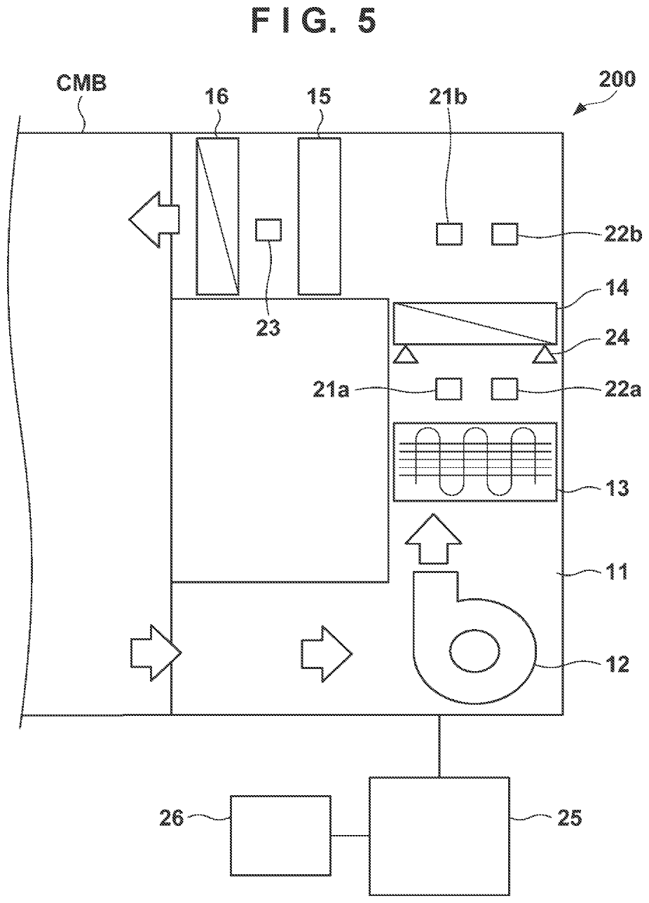

A cleaning apparatus 200 according to the second embodiment of the present invention will be described below. FIG. 5 is a schematic view showing an example of the arrangement of the cleaning apparatus 200 according to the second embodiment. The cleaning apparatus 200 according to this embodiment is different from the cleaning apparatus 100 of the first embodiment in that a humidity detector 21 and a temperature detector 22 have different arrangements. Note that this embodiment basically takes over the first embodiment, and matters other than those to be described below follow the first embodiment.

The humidity detector 21 according to this embodiment is arranged to detect the humidity of the gas on each of the upstream side and the downstream side of a chemical filter 14 in a gas flow path 11. More specifically, the humidity detector 21 can include a first humidity detector 21a for detecting the humidity of the gas on the upstream side of the chemical filter 14 in the gas flow path 11 and a second humidity detector 21b for detecting the humidity of the gas on the downstream side of the chemical filter 14 in the gas flow path 11.

The temperature detector 22 according to this embodiment is arranged to detect the temperature of the gas on each of the upstream side and the downstream side of a chemical filter 14 in a gas flow path 11. More specifically, the temperature detector 22 can include a first temperature detector 22a for detecting the temperature of the gas on the upstream side of the chemical filter 14 in the gas flow path 11 and a second temperature detector 22b for detecting the temperature of the gas on the downstream side of the chemical filter 14 in the gas flow path 11.

For example, if the humidity of the gas passing through the chemical filter 14 changes, the chemical filter 14 absorbs or evaporates the water of the chemical filter 14. More specifically, if the humidity of the gas passing through the chemical filter 14 increases, the chemical filter 14 adsorbs (absorbs) the water, so that the humidity on the downstream side of the chemical filter 14 is lower than that on the upstream side. By an influence of heat (adsorption heat) generated by the adsorption of water in the chemical filter 14, the temperature on the downstream side of the chemical filter 14 is higher than that on the upstream side. On the other hand, if the humidity of the gas passing through the chemical filter 14 decreases, the chemical filter 14 evaporates the water, so that the humidity on the downstream side of the chemical filter 14 is higher than that on the upstream side. In addition, by the influence of evaporation of the water in the chemical filter 14, the temperature on the downstream side of the chemical filter 14 is lower than that on the upstream side.

In this manner, if the humidities and temperatures of the gas different from each other on the upstream and downstream sides of the chemical filter 14 in the gas flow path 11, a state occurs in which the chemical filter 14 absorbs or evaporates the water. That is, the chemical filter 14 is set in an unsaturation state, and the weight of the chemical filter 14 is not stable. Therefore, if the measurement result of the weight measurement device 24 obtained in this state is used, it is difficult to precisely estimate the adsorption state of the organic substance in the chemical filter 14.

In a state in which the difference between the humidity detected by the first humidity detector 21a and the humidity detected by the second humidity detector 21b is smaller than the humidity threshold, the controller 25 according to this embodiment estimates the adsorption state of the organic substance in the chemical filter 14. In addition or alternatively, in a state in which the difference between the temperature detected by the first temperature detector 22a and the temperature detected by the second temperature detector 22b is smaller than the temperature threshold, the controller 25 estimates the adsorption state of the organic substance in the chemical filter 14. The humidity threshold and the temperature threshold are set as thresholds capable of determining the saturation state or a state near the saturation state of the chemical filter 14. Accordingly, the adsorption state of the organic substance in the chemical filter 14 set in the saturation state can be estimated with high precision. In this case, when the chemical filter 14 is set in the saturation state, the detection result of the first humidity detector 21a is almost equal to the detection result of the second humidity detector 21b. For this reason, the adsorption state of the organic substance in the chemical filter 14 may be estimated based on the detection result of one of the first humidity detector 21a and the second humidity detector 21b.

### <Embodiment of Lithography Apparatus>

An embodiment of a lithography apparatus according the present invention will be described. Examples of the lithography apparatus are an exposure apparatus for exposing a substrate and transferring a pattern of the original (mask) onto the substrate, an imprint apparatus for forming a pattern of an imprint material on a substrate using an original (mold), and the like. An imprint apparatus will be exemplified as the lithography apparatus.

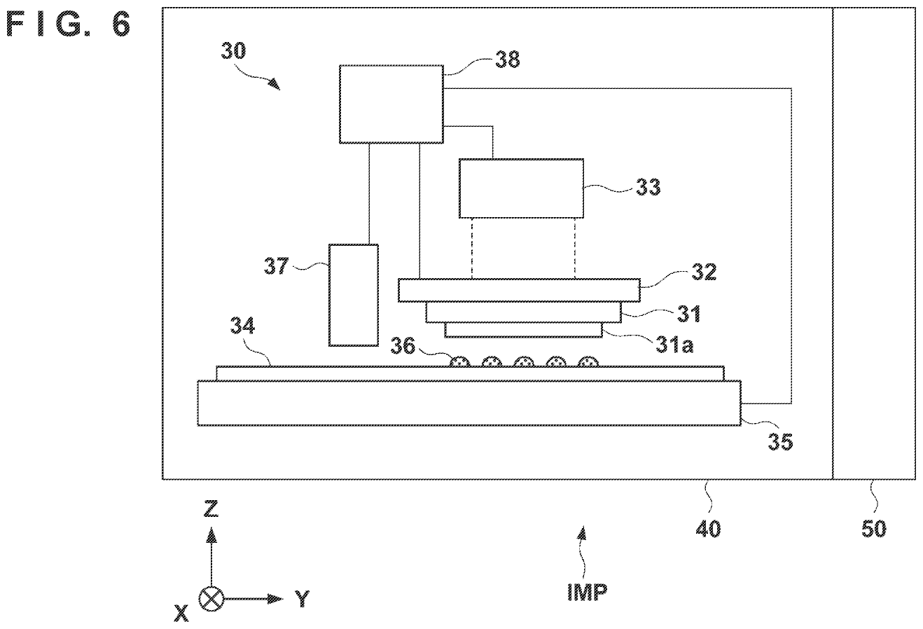

FIG. 6 is a schematic view showing an example of the arrangement of an imprint apparatus IMP as an example of the lithography apparatus of this embodiment. In FIG. 6, directions perpendicular to each other on a plane parallel to the surface of a substrate 34 are defined as X and Y directions, and a direction perpendicular to the X and Y directions is defined as a Z direction.

The imprint apparatus IMP can include a forming device 30 for forming a pattern on a substrate, a chamber 40 for accommodating the forming device 30, and a cleaning apparatus 50 for performing the gas cleaning in the chamber 40. The chamber 40 corresponds to the chamber CMB of the first or second embodiment. The cleaning apparatus 100 described with reference to the first embodiment or the cleaning apparatus 200 described with reference to the second embodiment can be applied as the cleaning apparatus 50.

The forming device 30 brings an imprint material 36 supplied onto the substrate 34 into contact with a mold 31, and applies curing energy to the imprint material 36, thereby forming, on the substrate 34, the pattern of the cured product to which a pattern having convex and concave portions of the mold 31 is transferred. More specifically, the forming device 30 cures the imprint material 36 in a state in which the imprint material 36 is supplied to the substrate 34 in the form of a plurality of droplets and the mold 31 on which the pattern having the concave and convex portions is formed is brought into contact with the imprint material 36 on the substrate 34. The interval between the mold 31 and the substrate 34 is widened to separate the mold 31 from the cured imprint material 36, so that the pattern of the mold 31 can be transferred to the imprint material 36 on the substrate 34. A series of operations is called an “imprint processing” and performed for each of the plurality of shot regions on the substrate 34.

As shown in FIG. 6, the forming device 30 according to this embodiment can include an imprint head 32 for holding the mold 31, a curing device 33, a stage 35 for holding the substrate 34, a supply device 37, and a controller 38. The controller 38 is formed by, for example, a computer including a CPU and a memory and executes the imprint processing by controlling the respective components of an imprint apparatus 10. Note that the controller 38 may be arranged independently of the controller 25 of the cleaning apparatus 50 (100 or 200), but may be arranged as part of the controller 25 or may include the controller 25 as part of the controller 38.

The mold 31 is usually formed from a material such as quartz capable of transmitting light (ultraviolet light). In the mold 31, a pattern having convex and concave portions to be transferred to imprint material 36 on a substrate is formed in a partial region 31a (mesa region) as part extending on the substrate side on the surface of the substrate side As the substrate 34, glass, ceramic, a metal, a semiconductor, a resin, or the like is used. A member made of a material different from that of the substrate may be formed on the surface of the substrate, as needed. More specifically, the substrate 34 is a silicon wafer, a semiconductor compound wafer, silica glass, or the like. An adhesive layer may be provided before the application of an imprint material to improve the adhesiveness between the imprint material and the substrate, as needed.

The imprint head 32 drives the mold 31 in the Z direction so that the mold 31 is held, the mold 31 is brought into contact with the imprint material 36 on the substrate 34, or the mold 31 is separated from the cured imprint material 36 on the substrate 34. The stage 35 drives the substrate 34 in the X and Y directions so that the substrate 34 is held, and alignment between the mold 31 and substrate 34 is performed. The curing device 33 cures the imprint material 36 by irradiating the imprint material 36 on the substrate 34 with light (for example, ultraviolet light) via the mold 31 in a state in which the mold 31 and the imprint material 36 on the substrate 34 are in contact with each other. In addition, the supply device 37 (dispenser) supplies the imprint material 36 onto the substrate 34 in the form of a plurality of droplets.

As the imprint material, a curable composition (to be also referred to a resin in an uncured state) that is cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like.

The curable composition is a composition cured by light irradiation or heating. A photo-curable composition cured by light contains at least a polymerizable compound and a photopolymerization initiator, and may contain a nonpolymerizable compound or a solvent as needed. The nonpolymerizable compound is at least one material selected from the group consisting of a sensitizer, a hydrogen donor, an internal mold release agent, a surfactant, an antioxidant, and a polymer component.

The imprint material is applied in a film shape onto the substrate by a spin coater or a slit coater. Alternatively, the imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

### <Embodiment of Article Manufacturing Method>

An article manufacturing method according to an embodiment of the present invention is suitable for manufacturing an article, for example, a microdevice such as a semiconductor device or an element having a fine structure. The article manufacturing method of this embodiment includes a step of forming a pattern on a substrate using the above lithography apparatus, a step of processing the substrate on which the pattern is formed via the forming step, and a step of manufacturing an article from the substrate having undergone the processing step. The manufacturing method also includes other known steps (for example, oxidation, deposition, vapor deposition, doping, planarization, etching, resist removal, dicing, bonding, and packaging). The article manufacturing method according to the embodiment is advantageous in at least one of the performance, quality, productivity, and production cost of the article, as compared to conventional methods.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-045787 filed on Mar. 22, 2023, which is hereby incorporated by reference herein in its entirety.

What is claimed is:

1. A cleaning apparatus for performing gas cleaning in a chamber, comprising:
a gas flow path configured to receive a gas in the chamber and send the gas to the chamber;
a filter arranged in the gas flow path and configured to adsorb an organic substance in a gas flowing through the gas flow path;
a weight measurement device configured to measure a weight of the filter;
a humidity detector configured to detect a humidity of a gas in the gas flow path; and
a controller configured to control the gas cleaning,
wherein the controller is configured to estimate an adsorption state of an organic substance in the filter based on a measurement result of the weight measurement device and a detection result of the humidity detector.

2. The apparatus according to claim 1, wherein the controller is configured to determine a water weight representing a weight of water contained in the filter, based on the detection result of the humidity detector, and estimate the adsorption state based on a value obtained by excluding a dry weight of the filter and the determined water weight from a weight of the filter measured by the weight measurement device.

3. The apparatus according to claim 2, wherein the controller is configured to determine the water weight based on the detection result of the humidity detector and information representing a relationship between a humidity of a gas in the gas flow path and a water content of the filter.

4. The apparatus according to claim 3, further comprising a temperature detector configured to detect a temperature in the gas flow path, wherein the controller has the information for each temperature of the gas in the gas flow path, and is configured to determine the water weight based on the information selected in accordance with the detection result of the temperature detector.

5. The apparatus according to claim 1, wherein the humidity detector is configured to detect a humidity of a gas on an upstream side of the filter in the gas flow path.

6. The apparatus according to claim 1, wherein
the humidity detector is configured to detect humidity of a gas on each of an upstream side and a downstream side of the filter in the gas flow path, and
the controller is configured estimate the adsorption state based on a measurement result of the weight measurement device and a detection result of the humidity detector, in a state in which a difference between the humidity of the gas on the upstream side and the humidity of the gas on the downstream side which are detected by the humidity detector is smaller than a humidity threshold.

7. The apparatus according to claim 1, further comprising a temperature detector configured to detect a temperature of a gas on each of an upstream side and a downstream side of the filter in the gas flow path,
wherein the controller is configured to estimate the adsorption state based on a measurement result of the weight measurement device and a detection result of the humidity detector, in a state in which a difference between the temperature of the gas on the upstream side and the temperature of the gas on the downstream side which are detected by the temperature detector is smaller than a temperature threshold.

8. The apparatus according to claim 1, wherein the controller is configured to estimate, as the adsorption state, one of an amount of an organic substance already adsorbed in the filter and an amount of a still adsorbable organic substance in the filter.

9. The apparatus according to claim 1, wherein the controller is configured to determine a replacement timing of the filter based on the adsorption state estimated for the filter.

10. The apparatus according to claim 9, wherein the controller is configured to notify the determined replacement timing of the filter.

11. A lithography apparatus for forming a pattern on a substrate, comprising:
a forming device configured to form a pattern on the substrate;
a chamber configured to accommodate the forming device; and
a cleaning apparatus defined in claim 1 and configured to perform gas cleaning in the chamber.

12. An article manufacturing method comprising:
forming a pattern on a substrate using a lithography apparatus defined in claim 11;
processing the substrate having undergone the forming; and
manufacturing an article from the substrate having undergone the processing.
